(19) United States
(12) Patent Application Publication
(10) Pub. No.: US 2018/0047567 A1
(43) Pub. Date: Feb. 15, 2018

(54) METHOD OF FABRICATING THIN FILM

(71) Applicant: SAMSUNG ELECTRONICS CO., LTD., Suwon-Si (KR)

(72) Inventor: JIN GYUN KIM, Suwon-Si (KR)

(21) Appl. No.: 15/391,348

(22) Filed: Dec. 27, 2016

Related U.S. Application Data
(60) Provisional application No. 62/372,491, filed on Aug. 9, 2016.

(51) Int. Cl. H01L 21/02; C23C 16/505; C23C 16/52; H01L 21/66; C23C 16/455

(52) U.S. Cl. CPC H01L 21/02252; H01L 21/022; H01L 21/02164; H01L 21/0214; H01L 21/0217; H01L 22/26; C23C 16/455; C23C 16/52; C23C 16/505

(57) ABSTRACT

A unit cycle process is repeatedly performed to form the thin film having a predetermined thickness. In the unit cycle process, a preliminary film layer is formed on a wafer and a thin film layer is formed on the wafer by converting the preliminary film layer to the thin film layer. The thin film layer is repeatedly formed on a thin film layer previously formed in the performing repeatedly of the unit cycle process.

### CROSS-REFERENCE TO RELATED APPLICATION

This application claims the benefit under 35 U.S.C. § 119(e) to U.S. Provisional Patent Application No. 62/372,491, filed on Aug. 9, 2016 in the United States Patent & Trademark Office, the disclosure of which is incorporated by reference herein in its entirety.

### TECHNICAL FIELD

The present inventive concept relates to a method of fabricating a thin film.

### DISCUSSION OF RELATED ART

In mobile electronic products, various semiconductor devices are used. As the mobile electronic products are becoming smaller in size, it demands that the various semiconductor devices be smaller in size. The semiconductor devices may include dielectric layers to provide as part of a capacitor, isolation of transistors or insulation of metal lines. The dielectric layers may also be referred to as insulating layers.

### SUMMARY

According to an exemplary embodiment of the present inventive concept, a method of fabricating a thin film is provided as follows. A unit cycle process is repeatedly performed to form the thin film having a predetermined thickness. In the unit cycle process, a preliminary film layer is formed on a wafer and a thin film layer is formed on the wafer by converting the preliminary film layer to the thin film layer. The thin film layer is repeatedly formed on a thin film layer previously formed in the performing repeatedly of the unit cycle process.

According to an exemplary embodiment of the present inventive concept, a method of fabricating a thin film is provided as follows. A deposition process is performed to form a preliminary film layer on a wafer in a first chamber. A plasma treatment process is performed on the wafer having the preliminary film layer in a second chamber to form a thin film layer. The performing of the deposition process and the performing of the plasma treatment process are repeatedly performed so that the thin film layer is repeatedly stacked on a thin film layer formed in a previous plasma treatment process to form a combined layer. A thickness of the combined layer increases as the performing of the deposition process and the performing of the plasma treatment process are repeated.

According to an exemplary embodiment of the present inventive concept, a method of fabricating a thin film is provided as follows. A plurality of wafers is loaded on a wafer holder in a chamber. The plurality of wafers is arranged on the wafer holder in a cycle. The chamber is set to have a plurality of process regions so that the plurality of process regions has a first setting for a deposition process and a second setting for a plasma treatment process. The first setting has at least two process regions of the plurality of process regions set for the deposition process and at least two process regions of the plurality of process regions set for a purging operation in the deposition process. The at least two process regions set for the deposition process are separated by each of the at least two process regions set for the purging operation. The second setting has at least three process regions of the plurality of process regions set for the plasma treatment process. The deposition process is performed to form a preliminary film layer by rotating the wafer holder so that each of the plurality of wafers goes through the at least two process regions set for the deposition process. The plasma treatment process is performed to form a thin film layer by rotating the wafer holder so that the preliminary film layer on each of the plurality of wafers is converted to the thin film layer in the at least three process regions set for the plasma treatment process. The thin film layer is between about 3 Å and about 50 Å.

### BRIEF DESCRIPTION OF DRAWINGS

These and other features of the present inventive concept will become more apparent by describing in detail exemplary embodiments thereof with reference to the accompanying drawings of which:

FIG. 1 show process steps of fabricating a thin film according to an exemplary embodiment of the present inventive concept;

FIG. 1A show process steps of fabricating a thin film according to an exemplary embodiment of the present inventive concept;

FIG. 2 shows a fabrication equipment of performing the process steps of FIG. 1 according to an exemplary embodiment of the present inventive concept;

FIGS. 3A to 3F show formation of the thin film according to the process steps of FIG. 1;

FIG. 4 shows a second chamber of the fabrication equipment of FIG. 2 according to an exemplary embodiment of the present inventive concept;

FIG. 5 show process steps of fabricating a thin film according to an exemplary embodiment of the present inventive concept;

FIG. 6 shows a fabrication equipment of performing the process steps of FIG. 1 according to an exemplary embodiment of the present inventive concept;

FIG. 7 show process steps of fabricating a thin film according to an exemplary embodiment of the present inventive concept; and

FIG. 8 shows a fabrication equipment of performing the process steps of FIG. 1 according to an exemplary embodiment of the present inventive concept.

It will be appreciated that for simplicity and clarity of illustration, elements illustrated in the drawings have not necessarily been drawn to scale. For example, the dimensions of some of the elements are exaggerated relative to other elements for clarity. Further, where considered appropriate, reference numerals have been repeated among the drawings to indicate corresponding or analogous elements.

### DETAILED DESCRIPTION OF EXEMPLARY EMBODIMENTS

Exemplary embodiments of the present inventive concept will be described below in detail with reference to the accompanying drawings. However, the inventive concept may be embodied in different forms and should not be construed as limited to the embodiments set forth herein. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present.

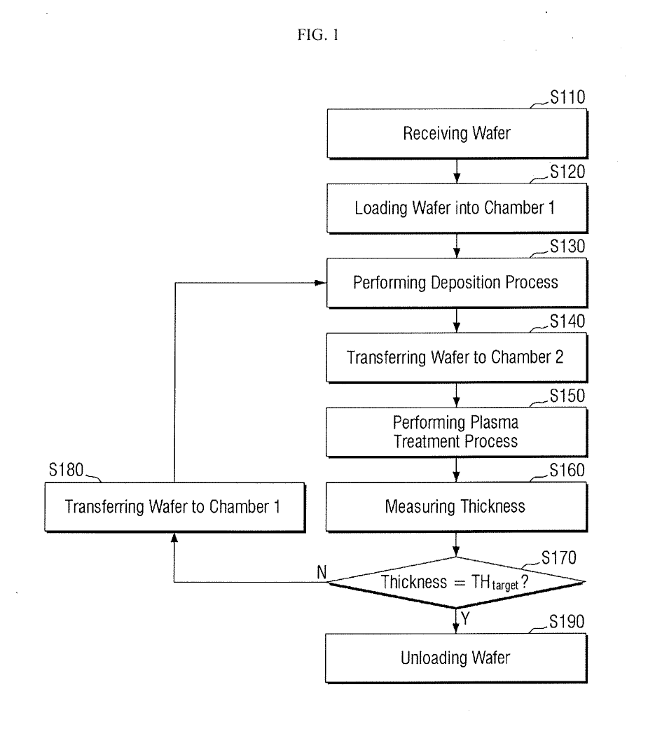

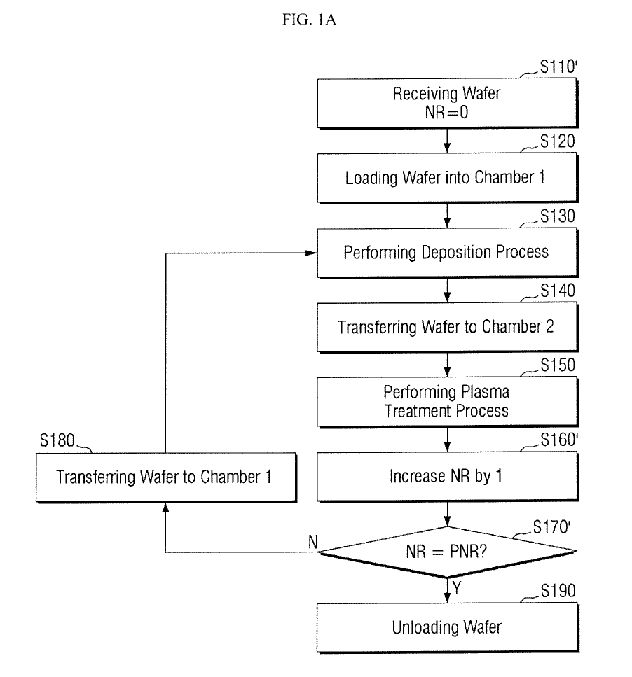

Hereinafter, it will be described that a thin film is fabricated according to an exemplary embodiment with reference to FIGS. 1 to 4.

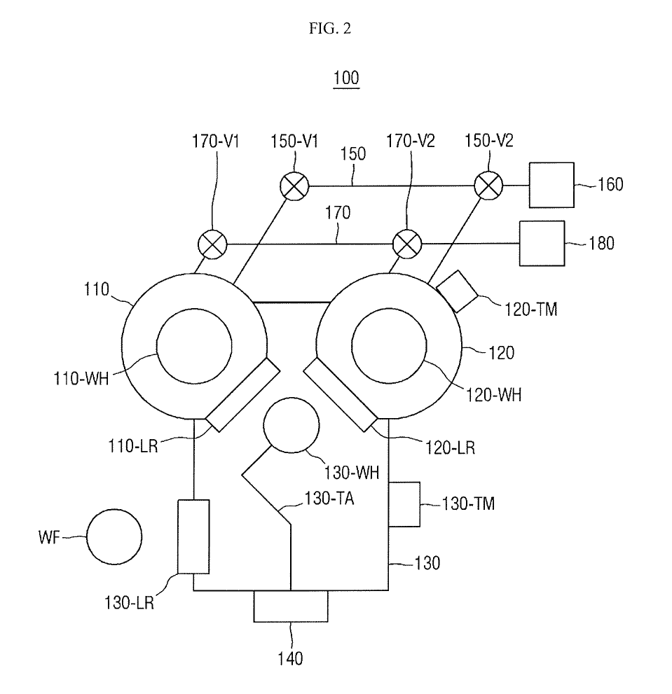

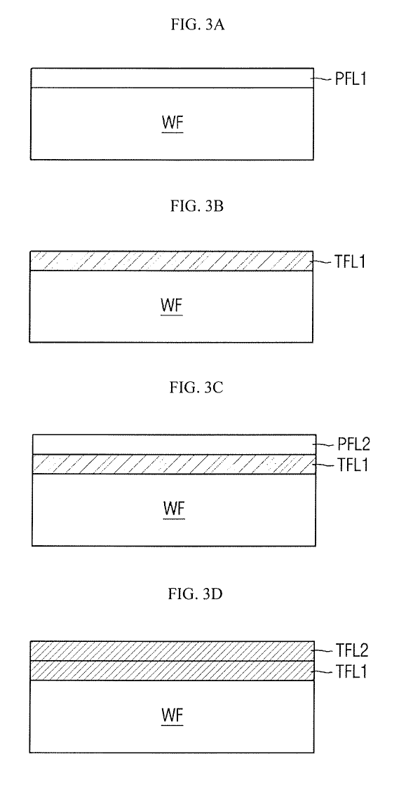

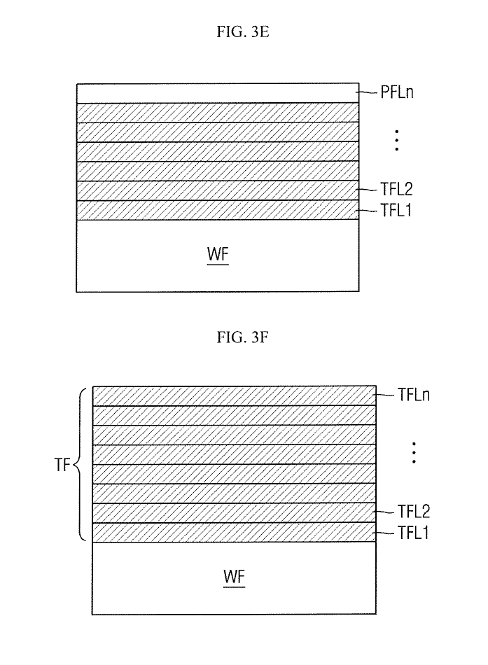

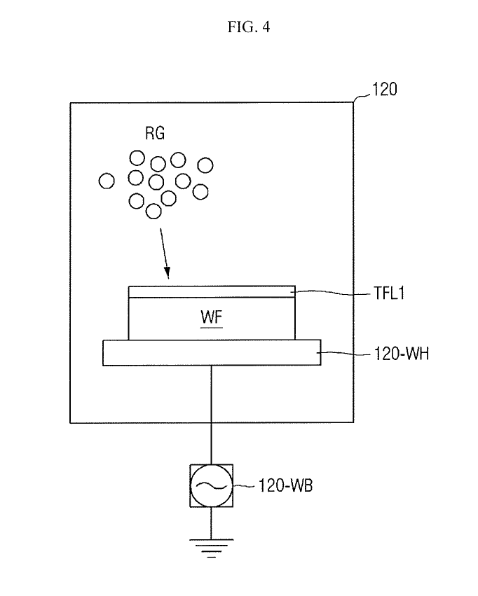

FIG. 1 show process steps of fabricating a thin film according to an exemplary embodiment of the present inventive concept. FIG. 2 shows a fabrication equipment of performing the process steps of FIG. 1 according to an exemplary embodiment of the present inventive concept. FIGS. 3A to 3E show formation of the thin film according to the process steps of FIG. 1. FIG. 4 shows a second chamber of the fabrication equipment of FIG. 2 according to an exemplary embodiment of the present inventive concept.

A fabrication equipment 100 includes a first chamber 110, a second chamber 120, a transfer chamber 130 and a controller 140.

The first chamber 110 is connected to an inlet line 150 through which a reactant gas is supplied from a gas source 160 to the first chamber 110 for a deposition process of step S130 in FIG. 1. The flow rate of the reactant gas may be controlled using a first inlet valve 150-V1. In an exemplary embodiment, the first inlet valve 150-V1 may include a mass flow controller.

In an exemplary embodiment, the reactant gas for the deposition process may include a silane (SiH4) gas, an oxygen (O2) gas or a nitrogen (N2) gas. The present inventive concept is not limited thereto. For example, the reactant gas may include a gas containing silicon (Si) including Si₂H₆, Si₃H₈, tris(dimethylamino)silane (TDMAS), Diisoprophylaminosilane (DIPAS), SiH₂Cl₂ or Si₂Cl₆ for depositing a silicon layer. For example, the reactant gas may include a gas containing oxygen (O) including O₃ for depositing a silicon oxide layer with the gas containing silicon. For example, the reactant gas may include a gas containing nitrogen (N) including NH₃ or N2H₂ for depositing a silicon nitride layer with the gas containing silicon. In an exemplary embodiment, the reactant gas may include NO or N2O for depositing a silicon oxynitride (SiON) with the gas containing silicon.

The first chamber 110 is also is connected to an outlet line 170 through which a pump 180 evacuates from the first chamber 110 the remaining reactant gas of the deposition process of step S130 and a byproduct gas generated in the deposition process of step S130. The evacuation rate may be controlled using a first outlet valve 170-V1.

The first chamber 110 includes a first load lock 110-LR and a first wafer holder 110-WH. A wafer on which the deposition process of step S130 is to be performed is transferred from the transfer chamber 130 to the first wafer holder 110-WH through the first load lock 110-LR.

The second chamber 120 is connected to the inlet line 150 through which a reactant gas is supplied to the second chamber 120 for a plasma treatment process of step S150 in FIG. 1. The flow rate of the reactant gas for the plasma treatment process may be controlled using a second inlet valve 150-V2. In an exemplary embodiment, the reactant gas for the plasma treatment process of step S150 may include an oxygen (O2) gas or a nitrogen (N2) gas. The present inventive concept is not limited thereto. For example, the reactant gas may include a gas containing oxygen (O) including O₃ for the plasma treatment process of step S150. For example, the reactant gas may include a gas containing nitrogen (N) including NH₃ or N2H₂ for the plasma treatment process.

In an exemplary embodiment, the inlet line 150 may be in plural so that the reactant gas of the deposition process and the reactant gas of the plasma treatment process are separately supplied using the first inlet valve 150-V1 and the second inlet valve 150-V2 to the first chamber 110 and the second chamber 120, respectively. In an exemplary embodiment, the gas source 160 may be in plural so that the reactant gas of the deposition process and the reactant gas of the plasma treatment process are separately supplied to the first chamber 110 and the second chamber 120, respectively.

The second chamber 120 is also connected to the outlet line 170 through which the pump 180 evacuates from the second chamber 120 the remaining reactant gas for the plasma treatment process of step S150. In an exemplary embodiment, the pump 180 may be shared by the first chamber 110 and the second chamber 120. In an exemplary embodiment, the pump 180 may be in plural so that the first chamber 110 and the second chamber 120 may be independently evacuated. In an exemplary embodiment, the outlet line 170 may be in plural so that the first chamber 110 and the second chamber 120 are independently evacuated.

The second chamber 120 also includes a second load lock 120-LR, a second wafer holder 120-WH and a first thickness monitor 120-TM. A wafer on which the deposition process of step S130 has been performed is transferred from the transfer chamber 130 to the second wafer holder 120-WH through the second load lock 120-LR.

The first thickness monitor 120-TM measures, in step S160 of FIG. 1, a thickness of a thin film layer formed on a wafer. In an exemplary embodiment, the thin film layer may include silicon oxide (SiO₂), silicon nitride (SiN) or silicon oxynitride (SiON). In an exemplary embodiment, the thickness of the thin film layer may be measured in situ. The present inventive concept is not limited thereto. For example, the thin film layer may include an insulating layer used in fabrication of a semiconductor device.

In an exemplary embodiment, the first thickness monitor 120-TM may include an ellipsometer or a reflectometer.

The transfer chamber 130 includes a transfer arm 130-TA, a third wafer holder 130-WH, a third load lock 130-LR and a second thickness monitor 130-TM. In an exemplary embodiment, the fabrication equipment 100 includes the first thickness monitor 120-TM attached to the second chamber 120 and the second thickness monitor 130-TM attached to the transfer chamber 130. The present inventive concept is not limited thereto. For example, the fabrication equipment 100 may include one of the first thickness monitor 120-TM and the second thickness monitor 130-TM.

A wafer WF on which the process steps of FIG. 1 are to be performed is transferred to the third wafer holder 130-WH from the external of the fabrication equipment 100 through the third load lock 130-LR. The transfer arm 130-TA transfers the wafer WF between the transfer chamber 130 and the first chamber 110, between the transfer chamber 130 and the second chamber 120 or between the transfer chamber 130 and the external of the fabrication equipment 100.

The controller 140 controls constituent elements of the fabrication equipment 100 according to the process steps of FIG. 1. For example, the controller 140 may perform the process steps of FIG. 1, controlling various constituent elements of the fabrication equipment 100 including the transfer arm 130-TA, various valves 170-V1, 170-V2, 150-V1 and 150-V2, or the pump 180, for example.

In an exemplary embodiment, the controller 140 may perform a software code of implementing the process steps of FIG. 1. Using the fabrication equipment 100, the process steps of FIG. 1 are performed as follows.

In step S110, the fabrication equipment receives a wafer WF. The wafer WF is loaded into the transfer chamber 130 through the third load lock 130-LR. The wafer WF is positioned on the third wafer holder 130-WH. In an exemplary embodiment, the wafer WF may be processed according to a fabrication process to form a semiconductor device before being transferred to the fabrication equipment 100. For example, the wafer WF may include a transistor formed in the fabrication process.

In step S120, the wafer WF on the third wafer holder 130-WH is loaded into the first chamber 110 through the first load lock 110-LR using the transfer arm 130-TA.

In step S130, a deposition process is performed on the wafer WF in the first chamber 110 to form a first preliminary film layer PFL1. As shown in FIG. 3A, the first preliminary film layer PFL1 is formed on an upper surface of the wafer WF. In an exemplary embodiment, the first preliminary film layer PFL1 may be formed of silicon, silicon oxide or silicon nitride. In an exemplary embodiment, the first preliminary film layer PFL1 may have a thickness greater than about 3 Å. In an exemplary embodiment, the first preliminary film layer PFL1 may have a thickness between about 3 Å and about 50 Å.

In step S140, the wafer WF having the first preliminary film layer PFL1 is transferred from the first chamber 110 to the second chamber 120 through the first load lock 110-LR and the second load lock 120-LR. For example, the transfer arm 130-TA receives through the first load lock 110-LR the wafer WF having the first preliminary film layer PFL1 from the first chamber 110 after the deposition process of step S130 is completed in the first chamber 110, transferring the wafer WF having the first preliminary film layer PFL1 from the first chamber 110 to the second chamber 120. The second chamber 120 receives the wafer WF having the preliminary film layer PFL through the second load lock 120-LR.

In step S150, a plasma treatment process is performed to form a first thin film layer TFL1. The plasma treatment process is performed on the wafer WF having the first preliminary film layer PFL1 in the second chamber 120 so that the first preliminary film layer PFL1 is converted to the first thin film layer TFL1. In an exemplary embodiment, the first preliminary film layer PFL1 is completely converted to the first thin film layer TFL1, as shown in FIG. 3B. In this case, the first preliminary film layer PFL1 may have a thickness to the extent that the first preliminary film layer PFL1 is completely converted to the first thin film layer TFL1.

In an exemplary embodiment, the plasma treatment process may include a plasma oxidation process or a plasma nitridation process. For example, if the first preliminary film layer PFL1 is formed a silicon layer and if the plasma treatment process is a plasma oxidation process, the first preliminary film layer PFL1 is converted to the first thin film layer TFL1 formed of a silicon oxide layer. For example, if the first preliminary film layer PFL1 is formed of a silicon layer and if the plasma treatment process is a plasma nitridation process, the first preliminary film layer PFL1 is converted to the first thin film layer TFL1 formed of a silicon nitride layer. For example, if the first preliminary film layer PFL1 is formed of a silicon oxide layer and if the plasma treatment process is a plasma nitridation process, the first preliminary film layer PFL1 is converted to the first thin film layer TFL1 formed of a silicon oxynitride (SiON) layer. For example, if the first preliminary film layer PFL1 is formed of a silicon nitride layer and if the plasma treatment process is a plasma oxidation process, the first preliminary film layer PFL1 is converted to the first thin film layer TFL1 formed of a silicon oxynitride (SiON) layer. The silicon layer is formed of silicon. The silicon oxide layer is formed of silicon oxide. The silicon nitride layer is formed of silicon nitride. The SiON layer is formed of silicon oxynitride.

In an exemplary embodiment, the second wafer holder 120-WH may be biased at a rf (radio frequency) bias voltage generated by a rf power source 120-WB, as shown in FIG. 4. The rf power source 120-WB is connected to the second wafer holder 120-WH. The first thin film layer TFL1 may be bombarded, in the process of the first thin film layer TFL1 being formed, with a reactant gas RG accelerated by the rf bias voltage, as shown in FIG. 4. The bombardment of the reactant gas RG may produce the first thin film layer TFL1 having more dense thin film quality.

In an exemplary embodiment, the reactant gas RG may be ionized in a plasma oxidation process or plasma nitridation process of the plasma treatment process of step S150 in FIG. 1, and the ionized reactant gas RG may be accelerated toward the wafer WF by the rf bias voltage.

In step S160, the first thickness monitor 120-TM or the second thickness monitor 130-TM measures a thickness of the first thin film layer TFL1 formed after step S150 is completed. generating a measured thickness. For example, the thickness measurement of the first thin film layer TFL1 may be performed in the second chamber 120 or the transfer chamber 130. Hereinafter, for the convenience of description, it is assumed that the first thickness monitor 120-TM measures the thickness of the first thin film layer TFL1.

In step S170, the controller 140 receives the measured thickness from the first thickness monitor 120-TM and determines whether the measured thickness of the first thin film layer TFL1 is substantially equal to a target thickness TH_{target}. If the measured thickness of the first thin film layer TFL1 is less than the target thickness TH_{target}, the process of FIG. 1 proceeds to step S180 to repeat the step S130 to the step S170. If the measured thickness of the first thin film layer TFL1 is substantially equal to the target thickness TH_{target}, the process proceeds to step S190 so that the wafer with the first thin film layer having the target thickness TH_{target} is unloaded from the second chamber 120 to the external of the fabrication equipment 100. The target thickness TH_{target} is a predetermined thickness of a thin film to be formed using the process steps of FIG. 1. In an exemplary embodiment, the target thickness TH_{target} may be set in the fabrication equipment 100.

The steps S130 and S150 may be referred to as a unit cycle process UCP. For example, one unit cycle process UPC includes the deposition process of step S130 and the plasma treatment process S150. In an exemplary embodiment, the unit cycle process UCP may be repeated until a thin film having the target thickness TH_{target} is obtained. Hereinafter, for the convenience of description, a unit cycle process UCP performed first in the process steps of FIG. 1 may be referred to as a first unit cycle process UCP-1; a unit cycle process performed immediately after the first unit cycle process UCP-1 may be referred to as a second unit cycle process UCP-2; a unit cycle process performed immediately after the second unit cycle process UCP-2 may be referred to as a third unit cycle process UCP-3. In this manner, a unit cycle process performed Nth from the first unit cycle process UCP-1 may be referred to as an Nth unit cycle process UCP-N.

In the first unit cycle process UCP-1 described above, if the measured thickness of the first thin film layer TFL1 is less than the target thickness TH_{target}, a second unit cycle process UCP-2 is performed.

In the second unit cycle process UCP-2, the steps S120 and S130 are performed on the wafer having the first thin film layer TFL1 so that a second preliminary film layer PFL2 is formed on the first thin film layer TFL1 as shown in FIG. 3C. In an exemplary embodiment, the second preliminary film layer PFL2 is in direct contact with the first thin film layer TFL1.

The steps S140 and S150 are performed on the wafer WF having the second preliminary film layer PFL2 to form a second thin film layer TFL2 on the first thin film layer TFL1, as shown in FIG. 3D. As described above, the second preliminary film layer PFL2 is converted to the second thin film layer TFL2. In an exemplary embodiment, the second preliminary film layer PFL2 is completely converted to the second thin film layer TFL2. In this case, the second preliminary film layer PFL2 may have a thickness to the extent that the second preliminary film layer PFL2 is completely converted to the second thin film layer TFL2.

In an exemplary embodiment, the second thin film layer TFL2 is in direct contact with the first thin film layer TFL1.

In steps S160 and S170, the first thickness monitor 120-TM measures a thickness of a combined layer of the first thin film layer TFL1 and the second thin film layer TFL2 to generate a measured thickness. The measured thickness is outputted to the controller 140. In an exemplary embodiment, the thickness monitor 120-TM measures the first thin film layer TFL1 and the second thin film layer TFL2 in total.

If the controller 140 determines that the measured thickness is substantially the same with the target thickness TH_{target}, a thin film including the first thin film layer TFL1 and the second thin film layer TFL2 is formed. In this case, in step S190, the wafer WF is unloaded from the fabrication equipment 100 to the external. The wafer WF includes the first thin film layer TFL1 and the second thin film layer TFL2, of which a combined thickness is the target thickness TH_{target}; and the thin film is formed of the two thin film layers of the first thin film layer TFL1 and the second thin film layer TFL2.

If the controller 140 determines that the measured thickness is less than the target thickness TH_{target}, the process steps of FIG. 1 proceed to the step S180 to perform a third unit cycle process UCP-3 including steps S130 and S150.

For the convenience of description, it is assumed that an Nth unit cycle process UCP-N is performed to form a thin film TF having the target thickness TH_{target}, as shown in FIGS. 3E and 3F. In the Nth unit cycle process, an Nth preliminary film layer PFLn is formed on a thin film layer formed in a previous unit cycle process using the deposition process of S130 as shown in FIG. 3E, and the Nth preliminary film layer PFLn is converted to an Nth thin film layer TFLn as shown in FIG. 3F.

The thin film TF may include the first thin film layer TFL1, the second thin film layer TFL2, . . . , and the Nth thin film layer TFLn. In an exemplary embodiment, the thin film TF may be formed using two or more unit cycle processes UCP.

Each of the first preliminary film layer PFL1, the second preliminary film layer PFL2, . . . , the Nth preliminary film layer PFLn may be referred to as a preliminary film layer PFL; each of the first thin film layer TFL1, the second thin film layer TFL2, . . . , the Nth thin film layer TFLn may be referred to as a thin film layer TFL. A combined layer of the first thin film layer TFL1, the second thin film layer TFL2, . . . , the Nth thin film layer TFLn, if a thickness of the combined layer is substantially equal to the target thickness TH_{target}, may be referred to as a thin film TF, as shown in FIG. 3F.

In an exemplary embodiment, the thin film TF is formed in a piecemeal manner by repeatedly performing the deposition process of step S130 and the plasma treatment process of step S150 until a combined layer of thin film layers formed in the piecemeal manner has the target thickness TH_{target}.

In an exemplary embodiment, the preliminary film layer PFL may have substantially the same thickness in each unit cycle process UCP. The present inventive concept is not limited thereto. For example, at least one preliminary film layer PFL may have different thickness from other preliminary film layers PFL. In an exemplary embodiment, the preliminary film layer PFL may have a decreasing thickness as the unit cycle process UCP is repeated. In this case, a preliminary film layer PFL formed later may have a thickness smaller than a thickness of a preliminary film layer PFL formed earlier in the process steps of FIG. 1.

In an exemplary embodiment, the deposition process of step S130 performs to form a preliminary film layer PFL including silicon. The plasma treatment process of step S150 includes a plasma oxidation process or a plasma nitridation process to convert silicon of the preliminary film layer PFL to a thin film layer TFL of silicon oxide or a thin film layer TFL of silicon nitride, respectively.

In an exemplary embodiment, the deposition process of step S130 performs to form a preliminary film layer PFL including silicon oxide. The plasma treatment process of step S150 may include a plasma nitridation process to convert the silicon oxide of the preliminary film layer PFL to a thin film layer TFL formed of silicon oxynitride (SiON).

In an exemplary embodiment, the deposition process of step S130 performs to form a preliminary film layer PFL including silicon nitride. The plasma treatment process of step S150 may include a plasma oxidation process to convert the preliminary film layer PFL formed of the silicon nitride to a thin film layer formed of silicon oxynitride (SiON).

The process steps of FIG. 1 repeats the unit cycle process UCP according to a decision of whether a thickness of a combined layer of thin film layers is substantially equal to the target thickness TH_{target}. In an exemplary embodiment, the controller 140 of FIG. 2 performs the decision based on a measured thickness of the combined layer.

The present inventive concept is not limited thereto. For example, the step S160 is performed only after the unit cycle process UCP is repeated in a predetermined number of repeat PR as shown in FIG. 1A. The process steps of FIG. 1A are substantially the same as the process steps of FIG. 1, except that the process steps of FIG. 1A is performed without measuring a thickness of a combined layer of thin film layers formed in repeatedly performing of the step S130 and the step S150. In this case, the predetermined number of repeat PR may be set based on the target thickness TH_{target}, a unit thickness of a preliminary film layer PFL or a process time. In an exemplary embodiment, the unit thickness of the preliminary film layer PFL may be set to have a thickness to the extent that the preliminary film layer PFL is completely converted to a thin film layer TFL in the plasma treatment process of step S150 in FIG. 1.

A number of repeat NR, set to zero in step S110′, increases by one after a step S130 and a step S150 are performed in step S160′. In step S170′, if the number of repeat NR is not equal to the predetermined repeat PR, the process steps of FIG. 1A proceed to step S180; otherwise, a wafer is unloaded in step S190.

In an exemplary embodiment, after step S170′ and before step S190, a thickness of a combined layer of PR thin film layers may be measured to verify that the combined layer has the target thickness TH_{target}. The PR thin film layers are formed of a thin film layer in a number of PR.

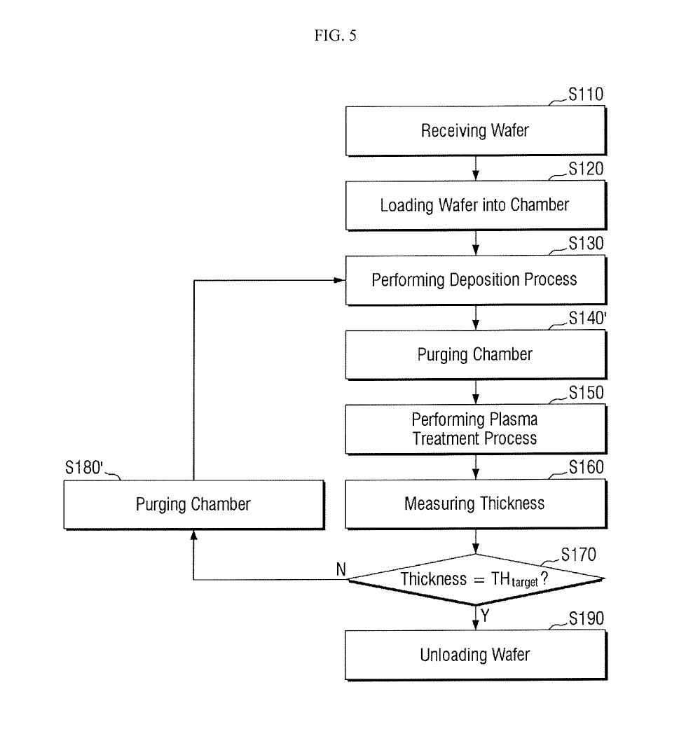

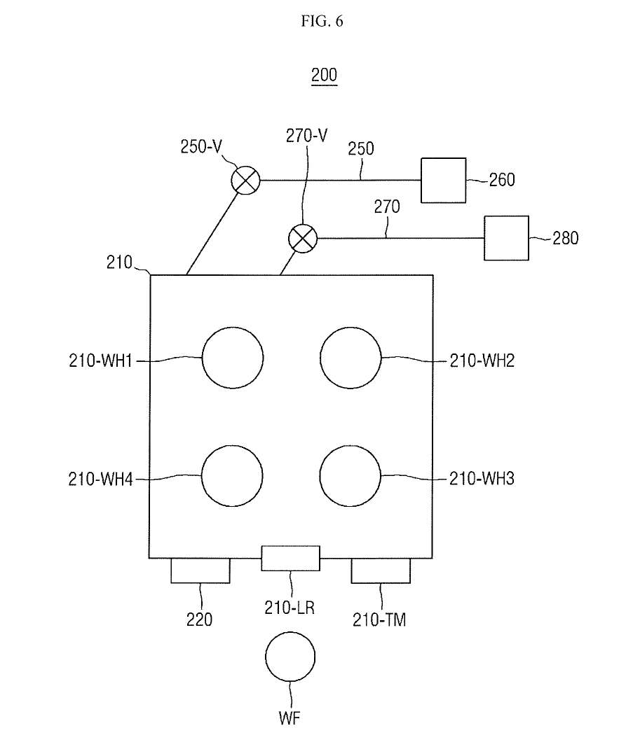

Hereinafter, it will be described that a thin film layer is fabricated according to an exemplary embodiment with reference to FIGS. 5 and 6.

FIG. 5 shows process steps of fabricating a thin film according to an exemplary embodiment of the present inventive concept. FIG. 6 shows a fabrication equipment of performing process steps of FIG. 5 according to an exemplary embodiment of the present inventive concept.

A fabrication equipment 200 includes a chamber 210, a plurality of wafer holders 210-WH1 to 210-WH4, a load lock 210-LR, a thickness monitor 210-TM and a controller 220.

The chamber 210 is connected to an inlet line 250 through which a reactant gas is supplied from a gas source 260 to the chamber 210 for a deposition process of step S130 in FIG. 5. The flow rate of the reactant gas may be controlled using an inlet valve 250-V. In an exemplary embodiment, the inlet line 250 may supply a purging gas to the chamber 210. In an exemplary embodiment, the purging gas may be supplied using a separate inlet line different from the inlet line 250. In an exemplary embodiment, the purging gas may include nitrogen or argon.

The chamber 210 is also connected to an outlet line 270 through which a pump 280 evacuates from the chamber 210 the remaining reactant gas of the deposition process of step S130 and a byproduct gas generated in the deposition process of step S130. The evacuation rate may be controlled using an outlet valve 270-V. In an exemplary embodiment, the chamber 210 is purged using the purging gas through the outlet line 270. In an exemplary embodiment, a separate outlet line other than the outlet line 270 may be connected between the chamber 210 and the pump 280 to purge the chamber 210 using the purging gas.

The chamber 210 includes a load lock 210-LR and a plurality of wafer holders 210-WH1 to 210-WH4. In an exemplary embodiment, each of the plurality of wafer holders 210-WH1 to 210-WH4 may hold a wafer. In this case, the chamber 210 may apply the process steps of FIG. 5 to four wafers simultaneously. For the convenience of description, the chamber 210 includes four wafer holders 210-WH1 to 210-WH4. However, the present inventive concept is not limited thereto. The chamber 210 may include more than four wafer holders or less than four wafer holders. As shown in FIG. 4, each of the plurality of wafer holders 210-WH1 to 210-WH4 may be biased using the rf power source 120-WB.

The chamber 210 is supplied with a reactant gas for a plasma treatment process of step S150 in FIG. 5. In an exemplary embodiment, the inlet line 250 and the inlet valve 250-V may supply the reactant gas for the plasma treatment process. In an exemplary embodiment, the inlet line 250 may be plural, and the reactant gas for the plasma treatment process may be supplied through a different inlet line from an inlet line for the deposition process. In an exemplary embodiment, the inlet valve 250-V may be in plural. The flow rate of the reactant gas for the deposition process may be controlled using the inlet valve 250-V. The flow rate of the reactant gas for the plasma treatment process may be controlled using the inlet valve 250-V. In an exemplary embodiment, the inlet valve 250-V may include a mass flow controller.

The thickness monitor 210-TM and the controller 220 are the same as the first thickness monitor 120-TM of FIG. 2 and the controller 140 of FIG. 2, respectively. For the convenience of description, repeated description of the thickness monitor 210-TM will be omitted.

In an exemplary embodiment, the controller 240 may performs a software code implementing the process steps of FIG. 5. Using the fabrication equipment 200, the process steps of FIG. 5 are performed as follows.

The process steps of FIG. 5 are substantially the same as the process steps of FIG. 1. Differences between the process steps of FIG. 5 and the process steps of FIG. 1 will be described.

The deposition process of step S130 and the plasma treatment process of step S150 are performed in the same chamber 210 receiving four wafers. Each of the four wafers is placed on one of the four wafer holders 210-WH1 to 210-WH4.

Between the deposition process of step S130 and the plasma treatment process of step S150 is the chamber 210 purged in step S140′. In step S140′, the chamber 210 is purged using a purging gas including nitrogen or argon, for example, after the deposition process of step S130 is completed and before the plasma treatment process of step S150 is started.

Between the step S170 and the deposition process of step S130 is the chamber 210 purged in step S180′. In step S180′, the chamber 210 is purged using a purging gas including nitrogen or argon, for example, before the deposition process of S130 is started.

In step S160, a thickness of a thin film layer is measured using the thickness monitor 210-TM. In an exemplary embodiment, the thickness monitor 210-TM measures a thickness of a thin film layer from one of the four wafer holders 210-WH1 to 210-WH4.

Step S170 of FIG. 5 is performed as described with reference to FIGS. 1 to 4.

In an exemplary embodiments, four wafers are simultaneously processed according to the process steps of FIG. 5. The process steps of FIG. 1 are performed in two chambers 110 and 120 in which the deposition process S130 is performed in the first chamber 110 and the plasma treatment process S150 is performed in the second chamber 120. However, the process steps of FIG. 5 are performed in the same chamber 210, without transferring wafers. Instead, the purging steps S140′ and S180′ are performed between the deposition process S130 and the plasma treatment process S150.

A wafer on each of the plurality of wafer holders is processed as described with reference to FIGS. 3A to 3F. In an exemplary embodiment, the thin film TF is formed in a piecemeal manner by repeatedly performing the deposition process of step S130 and the plasma treatment process of step S150 until a combined layer of each thin film layer formed in the piecemeal manner has the target thickness TH_{target}.

The present inventive concept is not limited thereto. For example, as described in FIG. 1A, the step S110, S160 and S170 of the process steps of FIG. 5 may be replaced with the step S110′, S160′ and S170′ as described with respect to FIG. 1A.

In this case, after step S170′ and before step S190, a thickness of a combined layer of PR thin film layers for each of the four wafers may be measured to verify that each of the four wafers has the combined layer having the target thickness TH_{target}.

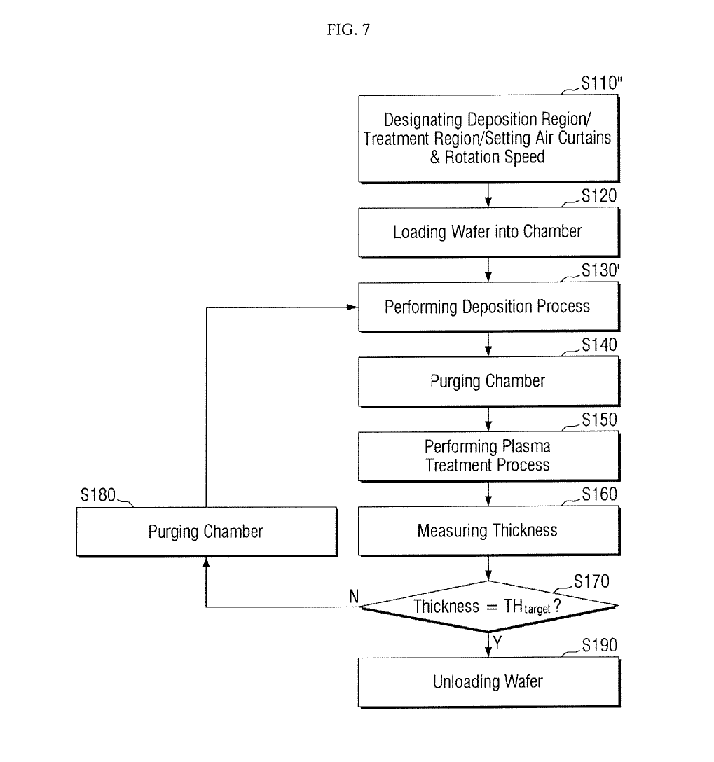

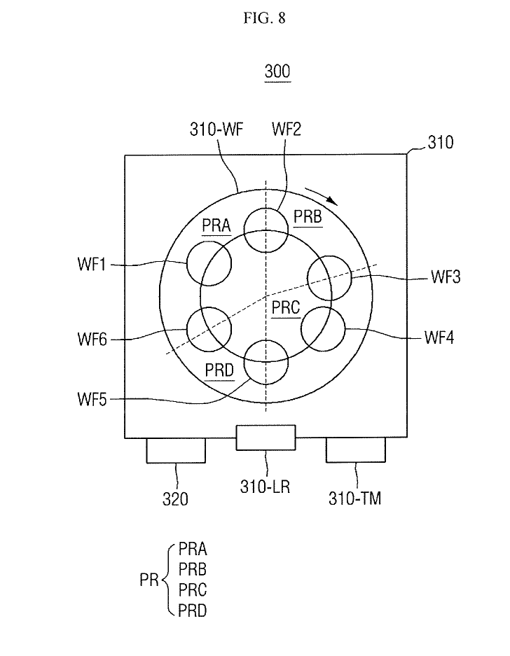

Hereinafter, it will be described that a thin film layer is fabricated according to an exemplary embodiment with reference to FIGS. 7 and 8.

FIG. 7 shows process steps of fabricating a thin film according to an exemplary embodiment of the present inventive concept. FIG. 8 shows a fabrication equipment of performing the process steps of FIG. 7 according to an exemplary embodiment of the present inventive concept.

A fabrication equipment 300 includes a chamber 310, a controller 320, a wafer holder 310-WF, a thickness monitor 310-TM, and a load lock 310-LR. The constituent elements having the same name as used in FIG. 2 are the same with the constituent elements of FIG. 2. The descriptions of the same elements will be omitted. For the convenience of description, constituent elements related with a gas supply or a gas exhaust are not shown in FIG. 8 and the descriptions thereof will be omitted.

The wafer holder 310-WF holds six wafers WF1 to WF6 arranged in a circular manner.

The chamber 310 includes a process region PR having four process regions PRA, PRB, PRC and PRD arranged in clockwise. Each of the four process regions PRA to PRD may perform at least one process of a deposition process and a plasma treatment process. In an exemplary embodiment, in the deposition process, at least one process region may be set as a purging region for the deposition process. In the purging region, an air curtain is formed to confine a reactant gas within a deposition region. Hereinafter, a process region may be referred to as a deposition region when a deposition process occurs in the process region; a process region may be referred to as a purging region when a purging operation occurs in the process region; and a process region may be referred to as plasma treatment region when a plasma treatment process occurs in the process region. In an exemplary embodiment, the purging operation is performed as part of the deposition process of forming silicon oxide or silicon nitride as a preliminary film layer. In this case, the purging operation is performed to form the air curtain in the purging region. Accordingly, the purging operation is different from steps S140 and S180 to evacuate the chamber 310.

For the convenience of a description, it is assumed that with reference to FIGS. 3A to 3F, a deposition process of S130′ is performed to form preliminary film layers PFL1, PFL2, . . . , PFLn formed of silicon oxide; and a plasma treatment process of S150 is performed to convert the preliminary film layers PFL1, PFL2, . . . , PFLn to thin film layers TFL1, TFL2, . . . , TFLn formed of silicon oxynitride (SiON). For example, the plasma treatment process of step S150 includes a plasma nitridation process using a nitrogen plasma.

In step S110″, the chamber 310 is set to have the four process regions PRA to PRD. Each of the four process regions PRA to PRD is set to one of a deposition process of step S130′ and a plasma treatment process of step S140. For example, the process regions PRA and PRC are set for the deposition process of step S130. In this case, the process regions PRB and PRD are set as the purging region. The process regions PRB, PRC and PRD are set for the plasma treatment process of step S150. In this case, the second process region PRB is set to as the purging region for the deposition process of step S130′ and as the plasma treatment region for the plasma treatment process of step S150. The third process region PRC is set to as the deposition region for the deposition process of step S130′ and as the plasma treatment region for the plasma treatment process of step S150.

The wafer holder 310-WF is set to rotate at a first rotational speed in the deposition process of step S130′ and at a second rotational speed in the plasma treatment process of step S150.

In step S120, six wafers WF1 to WF6 are positioned on the wafer holder 310-WF. The present inventive concept is not limited thereto. For example, the wafer holder 310-WF may hold more than six wafers or less than six wafers.

In step S130′, the wafer holder 310-WF rotates at the first rotational speed. For example, the first rotational speed may be between about 0.5 revolutions per minute (rpm) and about 150 rpm.

In step S130, the deposition process of step S130′ is performed in the process regions PRA and PRC, and the process regions PRB and PRD serve as an air curtain which confines a reactant gas within each of the process regions PRA and PRC.

In the process of the deposition process of step S130′ being performed, the wafers WF1 to WF6 are rotated, going repeatedly through the process region A to the process region D clockwise. For example, a first wafer WF1 is positioned in a first process region PRA as shown in FIG. 8. As the wafer holder 310-WF rotates, the first wafer WF1 go through a second process region PRB, a third process region PRC and a fourth process region PRD clockwise.

When the first wafer WF1 is in the first process region PRA, the deposition process of step S130′ performs on the first wafer WF1. In this case, silicon is deposited on the first wafer WF1 at a first predetermined thickness. When the first wafer WF1 is in the third process region PRC, an oxidation process is performed on the WF1 to form oxide from the silicon deposited on the first wafer WF1. In an exemplary embodiment, the first predetermined thickness may be less than about 3 Å.

Each of the second process region PRB and the fourth process region PRD serves as a air curtain between the first process region PRA and the third process region PRC.

In step S130′, the wafer holder 310-WF continues to rotate until the silicon oxide formed in the third process region PRC has a second predetermined thickness. In an exemplary embodiment, the second predetermined thickness may be between about 3 Å and about 50 Å. In an exemplary embodiment, the second predetermined thickness may be substantially the same as the thickness of the preliminary film layer PFL in FIGS. 3A to 3F. In this case, the preliminary film layer PFL is formed in a piecemeal manner in the chamber 310 when the first wafer WF1 goes through the deposition regions PRA and PRC multiple times.

In step S140, the chamber 310 is purged with a purging gas including an argon gas or a nitrogen gas. In an exemplary embodiment, the rotational speed of the wafer holder 310-WF may be set to the second rotational speed for the plasma treatment process of S150. In an exemplary embodiment, the second rotational speed may be between about 0.5 rpm and about 150 rpm. In an exemplary embodiment, the first rotational speed and the second rotational speed may be substantially the same. In an exemplary embodiment, the first rotational speed and the second rotational speed may be different from each other. For example, the second rotational speed may be greater than the first rotational speed; or the second rotational speed may be smaller than the first rotational speed.

In step S150, the first wafer WF1 having the silicon oxide as a preliminary film layer PFL goes through the second process region PRB, the third process region PRC and the fourth process region PRD clockwise. Because the second process region PRB, the third process region PRC and the fourth process region PRD is set as the plasma treatment region, the silicon oxide is converted to silicon oxynitride by the plasma treatment process. For example, the plasma treatment process is a plasma nitridation process using a nitrogen plasma. In this case, the nitrogen plasma may be maintained in the plasma treatment region PRB, PRC and PRD, and the nitrogen plasma is not generated in the first process region PRA.

The remaining process steps S160, S170 and S180 are substantially the same as the process steps S160, S170 and S180 of FIG. 5.

The first wafer WF1 is processed as described with reference to FIGS. 3A to 3F, except that each of the preliminary film layers PFL1, PFL2 . . . , PFLn formed according to the process steps of FIG. 7 is formed a cyclic process of a silicon deposition in the first process region PRA and a plasma oxidation in the third process region PRC. For example, the deposition process of S130′ is performed in a piecemeal manner until each of the preliminary film layers PFL1, PFL2, . . . , PFLn has the first predetermined thickness. In an exemplary embodiment, the thin film TF is formed in a piecemeal manner by repeatedly performing the deposition process of step S130′ and the plasma treatment process of step S150 until a combined layer of thin film layers TFL1, TFL2, . . . , TFLn formed in the piecemeal manner has the target thickness TH_{target}. A thickness of the combined layer increases as a number of the repeating of the performing of the deposition process of S130′ and the performing of the plasma treatment process S150.

In an exemplary embodiment, a deposition process of S130′ is performed to form a preliminary film layer PFL formed of silicon nitride; and a plasma treatment process of S150 is performed to convert the preliminary film layer PFL to a thin film layer TFL formed of silicon oxynitride (SiON). For example, the plasma treatment process of step S150 includes a plasma oxidation process using an oxygen plasma. In this case, the oxygen plasma may be maintained in the plasma treatment region including the second process region PRB, the third process region PRC and the fourth process region PRD, and the oxygen plasma is not generated in the first process region PRA.

In an exemplary embodiment, a deposition process of S130′ is performed to form a preliminary film layer PFL formed of silicon; and a plasma treatment process of S150 is performed to convert the preliminary film layer PFL to a thin film layer TFL formed of silicon oxide or silicon nitride. For example, the plasma treatment process of step S150 includes a plasma oxidation process using an oxygen plasma or a nitrogen plasma. In this case, the four process regions PRA to PRD are used to form silicon in the deposition process of S130′ without forming the air curtain in the process regions PRB and PRD as described above.

For the convenience of description, the process steps of FIG. 7 are described with respect to the first wafer WF1. The present inventive concept is not limited thereto. For example, each of the remaining wafers WF2 to WF6 is subject to the process steps described above with respect to the first wafer WF1.

The present inventive concept is not limited thereto. For example, as described in FIG. 1A, the step S160 and S170 of the process steps of FIG. 5 may be replaced with the step S160′ and SI70′ as described with respect to FIG. 1A. In step S110″, the number of repeat NR may be set to zero, as described with respect to FIG. 1A.

In this case, after step S170′ and before step S190, a thickness of a combined layer of PR thin film layers for each of the four wafers may be measured to verify that each of the four wafers has the combined layer having the target thickness TH_{target}.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A method of fabricating a thin film, comprising:
performing repeatedly a unit cycle process to form the thin film having a predetermined thickness,
wherein the unit cycle process comprises:
forming a preliminary film layer on a wafer; and
forming a thin film layer on the wafer by converting the preliminary film layer to the thin film layer,
wherein the thin film layer is repeatedly formed on a thin film layer previously formed in the performing repeatedly of the unit cycle process.

2. The method of claim 1,
wherein the unit cycle process is repeatedly in a predetermined number of repeat to form the thin film having the predetermined thickness, and
wherein the predetermined number of repeat is set before the performing repeatedly of the unit cycle process.

3. The method of claim 2,
wherein a thickness of the thin film is measured after the unit cycle process is repeatedly in the predetermined number of repeat.

4. The method of claim 1,
wherein the forming of the preliminary film layer includes a deposition process,
wherein the forming of the thin film layer is performed by a plasma oxidation process,
wherein the preliminary film layer is formed of silicon, and
wherein the thin film layer includes silicon oxide.

5. The method of claim 1,
wherein the forming of the preliminary film layer includes a deposition process,
wherein the forming of the thin film layer is performed by a plasma oxidation process,
wherein the preliminary film layer is formed of silicon nitride, and
wherein the thin film layer includes silicon oxynitride.

6. The method of claim 1,
wherein the forming of the preliminary film layer includes a deposition process,
wherein the forming of the thin film layer is performed by a plasma nitridation process,
wherein the preliminary film layer is formed of silicon, and
wherein the thin film layer includes silicon nitride.

7. The method of claim 1,
wherein the forming of the preliminary film layer includes a deposition process,
wherein the forming of the thin film layer is performed by a plasma nitridation process,
wherein the preliminary film layer is formed of silicon oxide, and
wherein the thin film layer includes silicon oxynitride.

8. The method of claim 1,
wherein the forming of the preliminary film layer of the unit cycle process includes:
performing repeatedly a deposition of a silicon layer and a oxidation process to form the preliminary film layer,
wherein the silicon layer has a thickness less than about 3 Å, and
wherein the preliminary film layer is formed of silicon oxide.

9. The method of claim 1,
wherein the forming of the preliminary film layer of the unit cycle process includes:
performing repeatedly a deposition of a silicon layer and a nitridation process to form the preliminary film layer,
wherein the silicon layer has a thickness less than about 3 Å, and
wherein the preliminary film layer is formed of silicon nitride.

10. A method of fabricating a thin film, comprising:
performing a deposition process to form a preliminary film layer on a wafer in a first chamber;
performing a plasma treatment process on the wafer having the preliminary film layer in a second chamber to form a thin film layer; and
repeating the performing of the deposition process and the performing of the plasma treatment process so that the thin film layer is repeatedly stacked on a thin film layer formed in a previous plasma treatment process to form a combined layer,
wherein a thickness of the combined layer increases as the performing of the deposition process and the performing of the plasma treatment process are repeated.

11. The method of claim 10, further comprising:
stopping the repeating of the performing of the deposition process and the performing of the plasma treatment process if the thickness of the combined layer is substantially equal to a predetermined thickness.

12. The method of claim 10,
wherein a thickness of the thin film layer is between about 3 Å and about 50 Å.

13. The method of claim 11,
wherein the repeating of the performing of the deposition process and the performing of the plasma treatment process further includes:
measuring the thickness of the combined layer after the plasma treatment process is performed; and
determining whether the thickness of the combined layer is substantially equal to the predetermined thickness,
wherein if the thickness of the combined layer is less than the predetermined thickness, the repeating of the performing of the deposition process and the performing of the plasma treatment process is continued.

14. The method of claim 10,
wherein the first chamber and the second chamber is a same chamber, and
wherein the wafer includes at least four wafers,
wherein the deposition process is simultaneously performed on the at least four wafers, and
wherein the plasma treatment process is simultaneously performed on the at least four wafers.

15. The method of claim 10,
the performing of the plasma treatment process includes biasing the wafer with a rf power source.

16. A method of fabricating a thin film, comprising:
loading a plurality of wafers on a wafer holder in a chamber,
wherein the plurality of wafers is arranged on the wafer holder in a cycle;
setting the chamber to have a plurality of process regions so that the plurality of process regions of the chamber has a first setting for a deposition process and a second setting for a plasma treatment process,
wherein the first setting has at least two process regions of the plurality of process regions set for the deposition process and at least two process regions of the plurality of process regions set for a purging operation in the deposition process,
wherein the at least two process regions set for the deposition process are separated by each of the at least two process regions set for the purging operation and
wherein the second setting has at least three process regions of the plurality of process regions set for the plasma treatment process;
performing the deposition process to form a preliminary film layer by rotating the wafer holder so that each of the plurality of wafers goes through the at least two process regions for the deposition process; and
perform the plasma treatment process to form a thin film layer by rotating the wafer holder so that the preliminary film layer on each of the plurality of wafers is converted to the thin film layer in the at least three process regions set for the plasma treatment process,
wherein the thin film layer is between about 3 Å and about 50 Å.

17. The method of claim 16,
wherein each of the at least two process regions for the purging operation forms a air curtain to confine a reactant gas for the deposition process with each of the at least two process regions for the deposition process.

18. The method of claim 17,
wherein the chamber is purged using a purging gas between the performing of the deposition process and the performing of the plasma treatment process.

19. The method of claim 16, further comprising:
repeating the performing of the deposition process and the performing of the plasma treatment process so that the thin film layer is repeatedly stacked on a thin film layer formed in a previous plasma treatment process to form a combined layer,
wherein a thickness of the combined layer increases as a number of the repeating of the performing of the deposition process and the performing of the plasma treatment process.

20. The method of claim 19,
wherein the repeating of the performing of the deposition process and the performing of the plasma treatment process further includes:
measuring a thickness of the combined layer after the plasma treatment process is performed; and
determining whether the thickness of the combined layer is substantially equal to a predetermined thickness,
wherein if the thickness of the combined layer is substantially equal to the predetermined thickness, the repeating of the performing of the deposition process and the performing of the plasma treatment process is stopped, and
wherein if the thickness of the combined layer is less than the predetermined thickness, the repeating of the performing of the deposition process and the performing of the plasma treatment process is continued.
